(19) United States
(12) Patent Application Publication
(10) Pub. No.: US 2015/0021772 A1
(43) Pub. Date: Jan. 22, 2015

(54) Mixed-metal barrier films optimized by high-productivity combinatorial PVD

(71) Applicant: Intermolecular Inc., San Jose, CA (US)

(72) Inventors: Edwin Adhiprakasha, Mountain View, CA (US); Sandip Niyogi, San Jose, CA (US); Karthik Ramani, Santa Clara, CA (US); Vivian Ryan, Berne, NY (US)

(21) Appl. No.: 13/943,418

(22) Filed: Jul. 16, 2013

(51) Int. Cl. H01L 21/768; H01L 23/48

(52) U.S. Cl. CPC H01L 21/76867; H01L 23/48
USPC 257/751; 438/653; 438/3

(57) ABSTRACT

A barrier film including at least one ferromagnetic metal (e.g., nickel) and at least one refractory metal (e.g., tantalum) effectively blocks copper diffusion and facilitates uniform contiguous (non-agglomerating) deposition of copper layers less than 100 Å thick. Methods of forming the metal barrier include co-sputtering the component metals from separate targets. Using high-productivity combinatorial (HPC) apparatus and methods, the proportions of the component metals can be optimized. Gradient compositions can be deposited by varying the plasma power or throw distance of the separate targets.

### BACKGROUND

Related fields include semiconductor manufacturing, particularly physical vapor deposition (PVD), and thin films of metal alloys.

Deposition processes are commonly used in semiconductor manufacturing to deposit a layer of material onto a substrate. (As used herein, “substrate” means an article on which materials are deposited; it may either be a bare bulk object or a composite object with one or more films already deposited on it). Physical vapor deposition (PVD) is one example of a deposition process, and sputter deposition or sputtering is a common physical vapor deposition method. In sputtering, ions or neutral species are ejected from a target material by high-energy particle bombardment and then deposited onto the substrate using plasma. Magnets may be positioned in the PVD chamber to localize the plasma. Some process sequences expose the surface to additional plasma or thermal treatment before or after the sputter deposition. For site isolated deposition (i.e., deposition on a site isolated region of the substrate), PVD tools typically include an aperture through which the sputtered material is targeted. While PVD tools are commonly used in the industry, they are limited to performing specific processes and do not permit much flexibility.

As feature sizes continue to shrink on semiconductor devices, improvements in materials, unit processes, and process sequences are continually sought. Evaluation and comparison of different materials, different unit process conditions and parameters, different process sequences and integrations, and combinations thereof may be done more rapidly if it is possible to process different isolated regions of the same substrate using different process conditions. This “multiple-samples-per-substrate” capability improves the efficiency of research and development, both by increasing the sample-generating speed (not needing a new substrate for every sample) and reducing the uncontrolled variables (substrate-to-substrate variations are not a factor if all the samples are on the same substrate). This capability, known as “combinatorial processing,” is generally performed with specially adapted tools rather than standard tools designed for conventional full-substrate processing. Some combinatorial-processing tools can subject isolated regions of the substrate to different processing conditions (e.g., localized deposition) in one step of a sequence and subject the full substrate to a substantially uniform processing condition (e.g., full-substrate deposition) in another step.

Further developments and improvements are needed to increase flexibility and throughput, and to accommodate new materials and processes, in both combinatorial and full-substrate processing.

As thin-film electronic devices and their features continue to shrink, the metallized lines and vias (conductors) interconnecting the devices must shrink, and they must also be packed more closely together with thinner insulators between them. Making the conductors thinner increases their interconnect resistance R. Packing the conductors more densely increases the parasitic capacitance C between neighboring conductors. These two factors cause an increased “interconnect RC delay,” which can become a limiting factor in processing speed.

The interconnect RC delay can be reduced by using a higher-conductivity material (e.g. copper) as the conductor and surrounding it with an insulator having a lower dielectric constant (“low-k” or “ultra-low-k” material). Implementation of these solutions is challenging because copper diffuses through dielectrics. Also, if the copper is near a silicon layer, it may form deep energy levels in silicon, and reacts with silicon to form silicides (although many devices place the copper so far from the silicon that these reactions are unlikely). All of these can cause device deterioration and failure.

To block copper diffusion, various barriers may be placed between the copper and nearby materials. Desirable characteristics of a copper-diffusion barrier may include low resistivity, low reactivity with copper, good adhesion to copper and surrounding materials and, where high-aspect ratio features must be conformally coated, good step and bottom coverage to provide uniform thickness over side-walls and bottoms of trenches as well as on plateaus. “Conformal” as used herein means that the film thickness at the bottom of a trench (or other recessed feature such as a via hole) is within about 15% of the film thickness on an upper plateau of the structure being coated. The processing parameters of the barrier (e.g. temperature and precursor composition) must also be compatible with other required processes and not harmful to other materials and structures on the substrate.

Refractory metals and their associated nitrides, such as tantalum (Ta) and tantalum nitride (TaN) are popular barrier materials. Unfortunately, copper films thinner than ˜100 Å are observed to agglomerate into non-contiguous islands after annealing when deposited on TaN/Ta barrier stacks. Therefore, a need exists for a barrier that will block copper diffusion and facilitate uniform, contiguous deposition of thin copper layers. In some applications it is also preferable that the barrier layer be as thin as possible.

### SUMMARY

The following summary presents some concepts in a simplified form as an introduction to the detailed description that follows. It does not necessarily identify key or critical elements and is not intended to reflect a scope of invention.

Some embodiments of a barrier made from a mixture of metals (“mixed-metal barrier”) block diffusion of material from a nearby conductor. When the conductor is deposited on the barrier in thin layers (e.g., about 100 Å or less), the conductor may form a contiguous film rather than agglomerating into islands of non-uniform thickness that may be separated by gaps.

Some embodiments of mixed-metal barriers include alloys. In some embodiments, the mixed metals include a ferromagnetic metal and a refractory metal. In some embodiments, the mixed metals include two different refractory metals. The contiguous conductor may include copper, the ferromagnetic metal may include nickel, and the refractory metal(s) may include tantalum or titanium.

Some embodiments of methods of metallizing a semiconductor device include depositing a mixed-metal barrier on a substrate. The deposition may involve co-sputtering different metals from separate targets. The targets may be sputtered at different levels of plasma power. The targets may be located at different distances from, or angles to, the substrate. A particularly strong magnetic field (e.g., >100 gauss) may be imposed near the substrate if one or more of the targets is ferromagnetic. A contiguous conductor less than about 100 Å thick may be deposited over the barrier.

Some embodiments of a thin-film stack include a mixed-metal barrier and a contiguous conductor less than about 100 Å thick near the barrier. The contiguous conductor may include copper and the mixed metals may include a refractory metal (e.g. tantalum) and either a ferromagnetic metal (e.g. nickel) or another refractory metal (e.g. titanium). In some embodiments where the mixed metals include a refractory metal and a ferromagnetic metal, a ratio of the refractory metal to the ferromagnetic metal may be greater than or equal to about 1:1. In some embodiments, the overall composition of the barrier layer may be at least about 50% refractory metal(s). An X-ray diffraction spectrum of the barrier may display different features than a simple superposition of the spectra of separate components of the barrier.

Some embodiments of a film stack include an insulator, a contiguous conductor less than about 100 Å thick, and a mixed-metal barrier between the insulator and the contiguous conductor. The insulator may include an oxide, the contiguous conductor may include copper, and the mixed-metal barrier may include either a refractory metal and a ferromagnetic metal or a pair of different refractory metals. At temperatures less than about 525 C, the barrier may block approximately all diffusion of material from the contiguous conductor into the oxide layer.

### BRIEF DESCRIPTION OF DRAWINGS

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 is a simplified schematic diagram illustrating an exemplary sputter processing chamber according to some embodiments.

FIGS. 5A and 5B are simplified schematic diagrams of part of a sputtering magnetron.

FIGS. 6A-6C conceptually illustrate conductor diffusion and a diffusion barrier.

FIGS. 7A and 7B conceptually illustrate contiguous and agglomerated films.

FIG. 8 is an example graph of X-ray diffraction (XRD) results plotting intensity vs. angle for mixed-metal barriers with different proportions of nickel and tantalum.

FIGS. 9A-9F conceptually illustrate a metallization process for a device structure using a mixed-metal barrier that is substantially conductive.

FIGS. 10A-10F conceptually illustrate a metallization process for a device structure using a mixed-metal barrier that is not substantially conductive.

FIG. 11 is an example flowchart for forming a mixed-metal barrier by simultaneous deposition.

FIG. 12 is an example flowchart for forming a mixed-metal barrier by alternating-layer deposition.

FIG. 13 is an example flowchart for HPC screening of candidate mixed-metal barriers.

### DETAILED DESCRIPTION OF EXAMPLE EMBODIMENTS

Some embodiments of the invention are directed to combined sputter deposition (“co-sputtering”) on a substrate from multiple targets. Each of the targets may be located in the same chamber as the substrate (the “deposition chamber”), or may be in a remote plasma chamber connected to the deposition chamber. Each target may be a different distance from the substrate and may be operated at a different plasma power. The plasma power for any of the targets may be adjusted in real time during sputter deposition.

The manufacture of semiconductor devices entails the integration and sequencing of many unit processing steps; for example, cleaning, surface preparation, deposition, patterning, etching, thermal annealing, and other related unit process steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as semiconductor devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009, the entireties of which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005, the entireties of which are all herein incorporated by reference.

HPC processing techniques have been successfully adapted to wet chemical processing such as etching, texturing, polishing, cleaning, etc. HPC processing techniques have also been successfully adapted to deposition processes such as sputtering, atomic layer deposition (ALD), chemical vapor deposition (CVD), and physical vapor deposition (PVD).

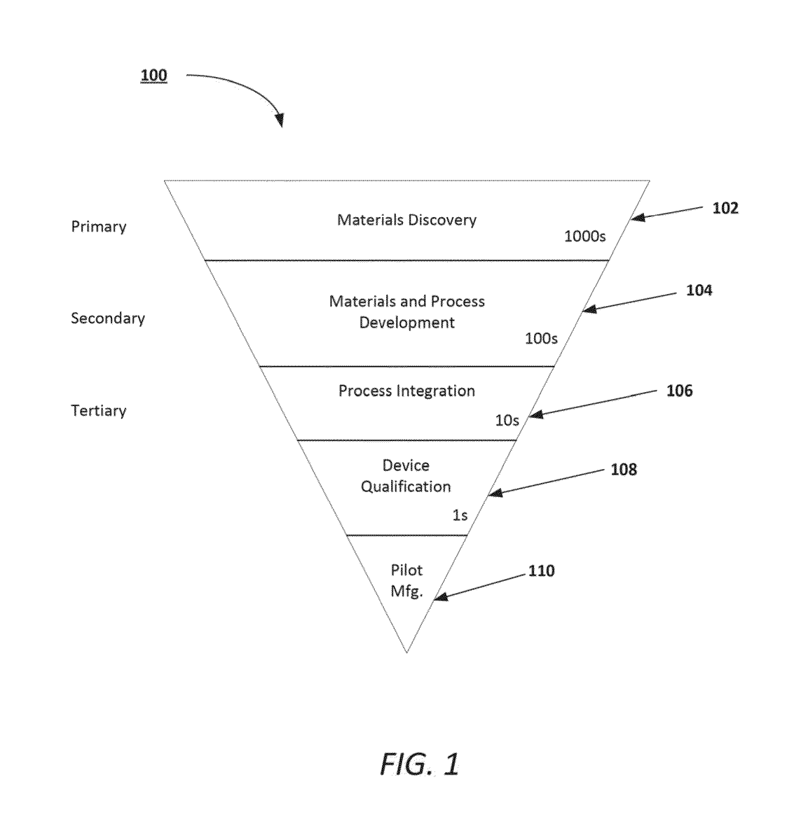

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

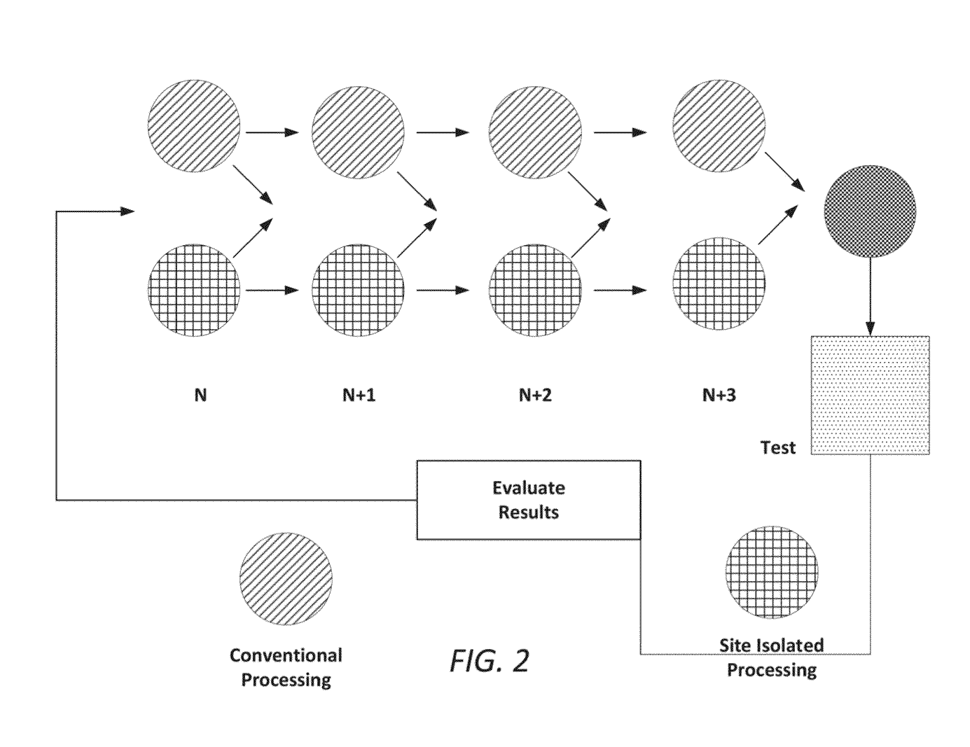

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It will be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It will be appreciated that these process parameters are exemplary and not meant to be an exhaustive list as other process parameters commonly used in semiconductor manufacturing may be varied.

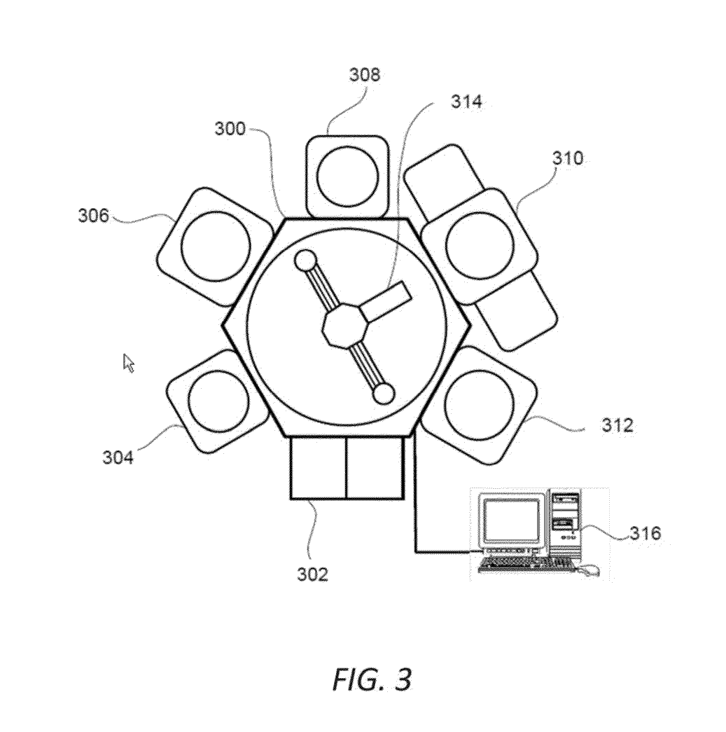

FIG. 3 is a simplified schematic diagram illustrating an integrated high productivity combinatorial (HPC) system in accordance with some embodiments of the invention. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. application Ser. No. 11/672,478 and Ser. No. 11/672,473, the entire disclosures of which are herein incorporated by reference. In a HPC system, a plurality of methods may be employed to deposit material upon a substrate employing combinatorial processes.

In some embodiments, a process chamber for combinatorial processing of a substrate is provided that includes two or more sputter targets configured to deposit material on the same substrate simultaneously (“co-sputtering”). The different targets' deposition parameters, including plasma power and distance from the substrate, may be varied. Some of the parameters, e.g. plasma power, may be independently varied in real time during a co-sputtering process. Other features of the deposition chamber, such as substrate supports and apertures, may be configured to allow sputter deposition on a site-isolated region of the substrate.

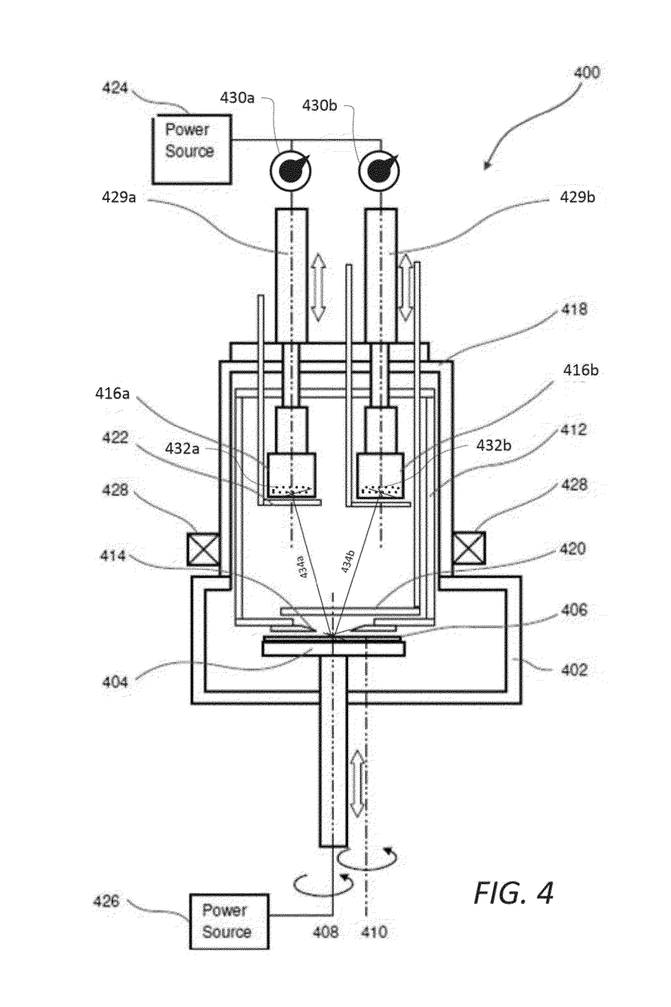

FIG. 4 is a simplified schematic diagram illustrating an exemplary process chamber 400 configured to perform combinatorial processing and full substrate processing in accordance with some embodiments of the invention. It will be appreciated that the processing chamber shown in FIG. 4 is merely exemplary and that other process or deposition chambers may be used with the invention. Further details on exemplary deposition chambers that can be used with the invention can be found in U.S. patent application Ser. No. 11/965,689, now U.S. Pat. No. 8,039,052, entitled “Multi-region Processing System and Heads”, filed Dec. 27, 2007, and claiming priority to U.S. Provisional Application No. 60/970,500 filed on Sep. 6, 2007, and U.S. patent application Ser. No. 12/027,980, entitled “Combinatorial Process System”, filed Feb. 7, 2008 and claiming priority to U.S. Provisional Application No. 60/969,955 filed on Sep. 5, 2007, the entireties of which are hereby incorporated by reference.

The processing chamber 400 includes a bottom chamber portion 402 disposed under a top chamber portion 418. A substrate support 404 is provided within the bottom chamber portion 402. The substrate support 404 is configured to hold a substrate 406 disposed thereon and can be any known substrate support, including but not limited to a vacuum chuck, electrostatic chuck or other known mechanisms.

The substrate 406 may be a conventional 200 mm and 300 mm wafer, or any larger or smaller size. In some embodiments, substrate 406 may be a square, rectangular, or other shaped substrate. The substrate 406 may be a blanket substrate, a coupon (e.g., partial wafer), or even a patterned substrate having predefined regions. In some embodiments, substrate 406 may have regions defined through site-isolated processing as described herein.

The top chamber portion 418 of the chamber 400 includes a process kit shield 412, which defines a confinement region over a portion of the substrate 406. As shown in FIG. 4, the process kit shield 412 includes a sleeve having a base (optionally integrated with the shield) and an optional top. It will be appreciated, however, that the process kit shield 412 may have other configurations. The process kit shield 412 is configured to confine plasma generated in the chamber 400 by sputter guns 416a and 416b. The positively-charged ions in the plasma strike a target and dislodge atoms from the target. The sputtered material is deposited on an exposed surface of substrate 406. In some embodiments, the process kit shield 412 may be partially moved in and out of chamber 400, and, in other embodiments, the process kit shield 412 remains in the chamber for both full substrate and combinatorial processing.

The base of process kit shield 412 includes an aperture 414 through which a surface of substrate 406 is exposed for deposition processing. The chamber may also include an aperture shutter 420 which is movably disposed over the base of process kit shield 412. The aperture shutter 420 slides across a bottom surface of the base of process kit shield 412 in order to cover or expose aperture 414. In some embodiments, the aperture shutter 420 is controlled by an arm extension (not shown) which moves the aperture shutter to expose or cover aperture 414.

Sputter guns 416a and 416b contain sputtering targets 432a and 432b. Targets 432a and 432b are made of the material(s) to be sputtered, and their compositions may differ. While two sputter guns with targets are illustrated, any number of sputter guns may be included, e.g., one, three, four or more sputter guns may be included. Where more than one sputter gun is included, the plurality of sputter guns may be referred to as a cluster of sputter guns.

A gun shutter 422 may be movably attached to one or more of the sputter guns (shown here on sputter gun 416a). Gun shutter 422 may block or shield the muzzle of a sputter gun that is not in current use, isolating one or more of the sputter guns from certain processes as needed. Gun shutter 422 may be integrated with the top of process kit shield 412 to cover the opening, automatically or manually, as the sputter gun is lifted. Individual gun shutters 422 can be used for each process gun 416a, 416b.

The sputter guns 416a and 416b are movable in a vertical direction so that one or both of the guns may be lifted from the slots of the shield. The angles of the sputter guns may also be varied. In some embodiments, sputter guns 416a and 416b are oriented or angled so that a normal reference line extending from a planar surface of the target of the process gun is directed toward an outer periphery of the substrate in order to achieve good uniformity for full substrate deposition film. Choice of a gun angle depends on target size, throw distance from target to substrate, target material, plasma power, sputter-gas pressure, and other process variables.

The sputter guns 416a and 416b may be fixed to arm extensions 429a and 429b to vertically move sputter guns 416a and 416b toward or away from top chamber portion 418. Each of the arm extensions 429a and 429b may be attached to a drive (e.g., lead screw, worm gear, or the like) enabling separate and independent control. The arm extensions 429a and 429b may be pivotally affixed to sputter guns 416a and 416b to enable the sputter guns to tilt relative to a vertical axis. In some embodiments, sputter guns 416a and 416b tilt toward aperture 414 when performing combinatorial processing and tilt toward a periphery of the substrate being processed when performing full substrate processing. Sputter guns 416a and 416b may alternatively tilt away from aperture 414. All these motions of the sputter guns 416a and 416b affect throw distances 434a and 434b from the centers of targets 432a and 432b to the center of substrate 406. Throw distances 434a and 434b are related to the length of a mean free path of sputtered atoms, molecules, or particles from targets 432a and 432b to substrate 406. The mean free path length may affect the density of the sputtered material at the substrate, kinetic energy with which the atoms, molecules, or particles strike the substrate. The mean free path may also affect the presence or population at substrate 406 of radical or excited species whose lifetime is equal to or less than the time it takes to travel the mean free path.

The chamber 400 also includes power sources 424 and 426. Power source 424 provides power for sputter guns 416a and 416b, and power source 426 provides RF power to bias the substrate support 404. In some embodiments, the output of the power source 426 is synchronized with the output of power source 424. The power source, 424, may be a direct current (DC) power supply, a direct current (DC) pulsed power supply, a radio frequency (RF) power supply, or a DC-RF imposed power supply. The power sources 424 and 426 may be controlled by a controller (not shown). The power to sputter guns 416a and 416b may be independently controlled by power controllers 430a and 430b. Their positions here are schematic, and they are not restricted to any particular physical position on or off chamber 400.

The chamber 400 may also include an auxiliary magnet 428 disposed around an external periphery of the chamber 400. The auxiliary magnet 428 is located between the bottom surface of sputter guns 416a and 416b and proximity of a substrate support 404. The auxiliary magnet may be positioned proximate to the substrate support 404, or, alternatively, integrated within the substrate support 404. The auxiliary magnet 428 may be a permanent magnet or an electromagnet. In some embodiments, the auxiliary magnet 428 improves ion guidance as the magnetic field above substrate 406 is re-distributed or optimized to guide the metal Ions. In some other embodiments, the auxiliary magnet 428 provides more uniform bombardment of ions and electrons to the substrate and improves the uniformity of the film being deposited.

The substrate support 404 is capable of both rotating around its own central axis 408 (referred to as “rotation” axis), and rotating around an exterior axis 410 (referred to as “revolution” axis). Such dual rotary substrate supports can be advantageous for combinatorial processing using site-isolated mechanisms. Other substrate supports, such as an XY table, can also be used for site-isolated deposition. In addition, substrate support 404 may move in a vertical direction. It will be appreciated that the rotation and movement in the vertical direction may be achieved through one or more known drive mechanisms, including, for example, magnetic drives, linear drives, worm screws, lead screws, differentially pumped rotary feeds, and the like.

Through the rotational movement of the process kit shield 412 and the corresponding aperture 414 in the base of the process kit shield, in combination with the rotational movement of substrate support 404, any region of a substrate 406 may be accessed for combinatorial processing. The dual rotary substrate support 404 allows any region (i.e., location or site) of the substrate 406 to be placed under the aperture 414; hence, site-isolated processing is possible at any location on the substrate 406. It will be appreciated that removal of the aperture 414 and aperture shutter 420 from the chamber 400 or away from the substrate 406 and enlarging the bottom opening of the process kit shield 412 allows for processing of the full substrate.

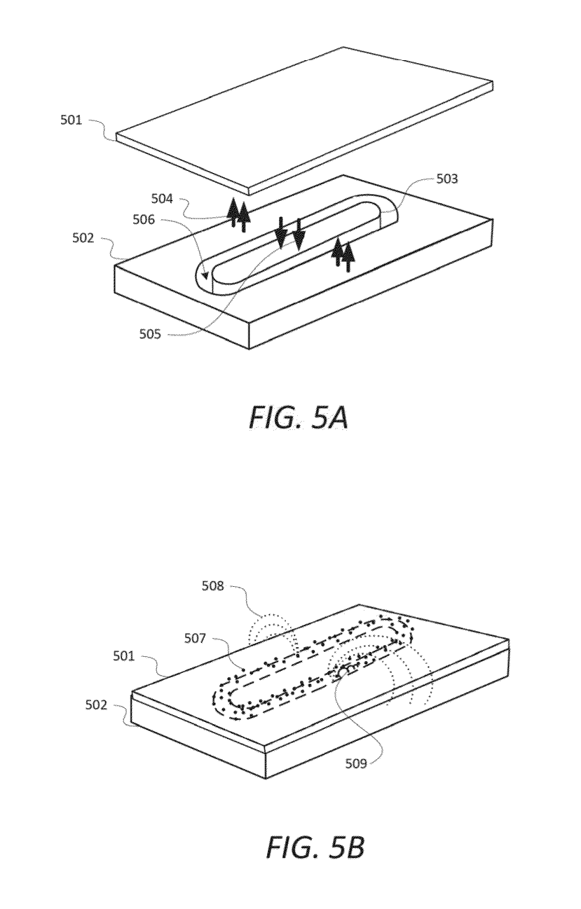

FIGS. 5A and 5B are simplified schematic diagrams of parts of a sputtering magnetron. FIG. 5A is an exploded view of the target and magnet array. Target 501 operates as a cathode and is placed over a magnet array that includes an outer magnet 502 and an inner magnet 503. Outer magnet 502 has a polarity 504 (e.g. “north”) and inner magnet 503 has the opposite polarity (e.g. “south”). Either or both magnets may be assembled from separate magnetic segments. When the magnetron operates, plasma will form over the target above gap 506 between the inner and outer magnets. This illustration shows an oval-annular “racetrack” shape for gap 506, but circular, rectangular, and other shapes are also used.

FIG. 5B is an assembled view showing plasma confinement zone 507 on target 501. The magnetic field created by outer magnet 502 and inner magnet 501 (not visible in this view) is represented by field lines 508. This magnetic field traps secondary electrons ejected from target 501 and re-shapes their trajectories into cycloidal paths 509, greatly increasing the probability that sputtering gas will ionize within the confinement zone 507. Positively charged ions from plasma confinement zone 507 are accelerated toward negatively biased target 501. The impacts of ions striking target 501 eject (sputter) target material from the target surface. Some of the sputtered target material lands on the substrate being processed (not shown in these views).

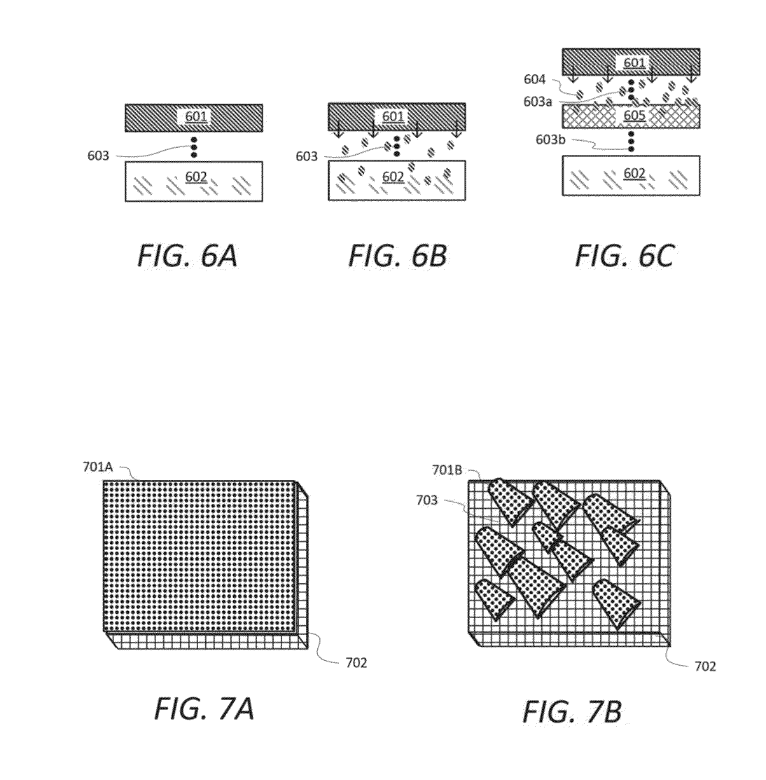

) FIGS. 6A-6C conceptually illustrate conductor diffusion and a diffusion barrier. As shown in FIG. 6A, many thin-film electronic devices have at least one conductor 601 and at least one insulator 602, which may (or may not) be separated by one or more intervening element(s) 603. Conductor 601, insulator 602, and intervening element(s) 603 may be layers, partial layers, or non-layer structures such as vias between layers or doped regions of layers. Although the illustration shows conductor 601 above insulator 602, they may be arranged in any relative orientation.

FIG. 6B shows a common failure mode of thin-film electronic devices. Over time, conductive material 604 may diffuse out of conductor 601. (For simplicity, the illustration shows diffusion in a downward direction, but diffusion can occur in any direction.) As conductive material 604 diffuses into insulator 602, insulator 602 becomes more conductive and less insulating. Eventually the conductivity of insulator 602 may rise enough to conduct current between device elements separated by the insulator (not shown here), creating an unwanted short circuit between the device elements and causing the device to fail.

FIG. 6C illustrates the function of a barrier. Barrier 605, which like the other elements may be a layer, partial layer, or non-layer structure, is interposed somewhere between conductor 601 and insulator 602. There may or may not be one or more intervening element(s) 603a (between conductor 601 and barrier 605) or 603b (between barrier 605 and insulator 602). If conductive material 604 diffuses out of conductor 601, it is trapped at or in barrier 605 and cannot reach insulator 602. Thus insulator 602 retains its insulating properties and the risk of device failure by a short circuit through insulator 602 is reduced. Barrier thicknesses can be on the order of nm to μm, with some materials functioning well at sub-nanometer thicknesses.

FIGS. 7A and 7B conceptually illustrate contiguous and agglomerated films. In FIG. 7A, a contiguous film 701A covers underlying material 702. A contiguous film has no gaps. Thus, if contiguous film 701A is, for example, a conductive film, any part of film 701A may be used as a conductor without creating an unintended open circuit. Other desirable qualities in a conductive film may include uniformity (or a non-uniformity that is intentionally imposed and controlled) of thickness, density, and composition, so that any part of the film selected to function as a conductor will behave predictably.

In FIG. 7B, an agglomerated film partially covers underlying material 702 with islands of film material 701b. Agglomerated islands 701b are separated by gaps 703. If film material 701b is intended to be a conductive film, sufficiently large gaps 703 may create unwanted open circuits. Furthermore, islands 701b have non-uniform thickness and may also be non-uniform in density or composition; even if an area selected as a conductor has no gaps, its behavior may be unpredictable.

Copper is an excellent conductor, and its higher conductivity than previously used conductive materials (e.g. aluminum) becomes more crucial as the dimensions of conductors are required to shrink along with other features of thin-film devices. Unfortunately, copper has a high diffusivity. The required smaller dimensions of insulators add to the problem because a thinner insulator needs less conductive contamination, compared to a thicker insulator, to risk a short circuit. Another challenge to effective use of very thin copper conductors is that copper agglomerates when annealed after deposition on some underlying materials. For example, when a layer of copper less than 100 Å thick is deposited on tantalum-nitride/tantalum (TaN/Ta), an effective diffusion barrier for copper, atomic-force microscopy (AFM) reveals trapezoid/pyramid-like shapes similar to islands 701B in FIG. 7B. If more copper is deposited for a thicker film, the film eventually becomes contiguous, like film 701A in FIG. 7A.

By contrast, copper deposited on some embodiments of a mixed-metal barrier (e.g., tantalum/nickel, tantalum/titanium) forms a contiguous film even if the copper thickness is less than 100 Å. In addition, some embodiments of a mixed-metal barrier effectively block copper diffusion at temperatures up to about 525 C.

Some embodiments of the mixed-metal barrier are formed by co-sputtering different metals from separate targets. Returning to FIG. 4, for example, simultaneous sputtering may be performed by sputter guns 416a and 416b, with one type of metal or alloy (e.g., a refractory metal) as target 432a and another type of metal or alloy (e.g., a ferromagnetic metal or a different refractory metal) as target 432b. The proportions of the two metals or alloys in the co-sputtered film may be adjusted by independently varying the plasma power at targets 432a and 432b (e.g., using power controllers 430a and 430b) or independently varying the throw distances 434a and 434b from the individual targets to substrate 406 (e.g., using arm extensions 429a and 429b to translate or tilt sputter guns 416a and 416b).

Some embodiments may be made by other types of simultaneous deposition from separate sources, such as atomic-layer deposition (ALD) from separate sources. Some embodiments may be made by non-simultaneous deposition, e.g. alternating or interleaved layers of the different metals that are then forced to interdiffuse by annealing. Once a composition is optimized for a desired use, a single target or other source with the desired composition may be made and used for single-source deposition (e.g. single-target sputtering).

In some embodiments, a diameter of 65 mm for aperture 414 in HPC sputter chamber 400 allows 9 different spots on a 300 mm substrate 406 to be separately processed. Thus, up to 9 different conditions (compositions, thicknesses, etc.) may be fabricated and tested in a single substrate run. The testing may include, without limitation, X-ray diffraction spectroscopy (XRD) of the processed test spots and depositing layers of copper less than about 100 Å thick over the test spots and examining their physical texture (e.g., contiguous or agglomerated) via atomic force microscopy.

Use of a ferromagnetic component in some embodiments of a mixed-metal barrier may suggest modifications to the methods of forming the barrier. Auxiliary magnet 428 may need to be stronger than is generally needed when sputtering non-ferromagnetic metals. In some embodiments, the magnetic field strength near the substrate is >100 gauss while sputtering the ferromagnetic metal. Additionally, the ferromagnetic target 432b may be constrained in thickness (e.g. <=about 0.5 mm). A thicker ferromagnetic target makes it more difficult to transmit a magnetic field through the target to create a sputtering plasma.

Returning to FIG. 6C, a film stack providing good conductivity without diffusion of conductive material 604 into insulator 602 can be assembled by making barrier 605 a mixed-metal barrier on at least one side of conductor 601, either with or without intervening layers 603a. Intervening layers 603b may or may not be between barrier 605 and insulator 601. In some embodiments, mixed-metal barrier 605 is formed on insulator 601, and conductor 602 is formed as a contiguous conductive film less than about 100 Å thick on mixed-metal barrier 605.

In some embodiments, the mixed-metal barrier may include co-sputtered nickel (a ferromagnetic metal) and tantalum (a refractory metal). The nickel plasma power may be about 50-200 W and the tantalum plasma power may be about 300-450 W for a 3-inch (˜7.5 cm) target diameter; this translates into power densities of ˜1.1-4.5 W/cm² for nickel and ˜6-10.2 W/cm² for tantalum. The magnetic field near the substrate may be about 100-500 gauss. The nickel target may be about 0.1-0.7 mm thick. The ratio of nickel to tantalum in the barrier may be 0.2:1-1:1 and the overall composition of the barrier may be about 10%-50% nickel. The barrier thickness may be between 0.2 and 50 nm, depending on variables of the rest of the device such as the amount of copper, exposure to conditions likely to cause copper diffusion (e.g. high temperatures), and sensitivity of the nearby layers to copper diffusion.

In some embodiments, the mixed-metal barrier may have a depth-wise composition gradient. The depth-wise composition gradient may be produced by varying the separate targets' relative plasma power, throw distance to the substrate, or both. The variation can be done in real time as the sputtering continues, if the process chamber is suitably configured. Alternatively, the mixed-metal barrier can be formed as several sub-layers and the variation can be done by adjusting parameters between depositions of the sub-layers.

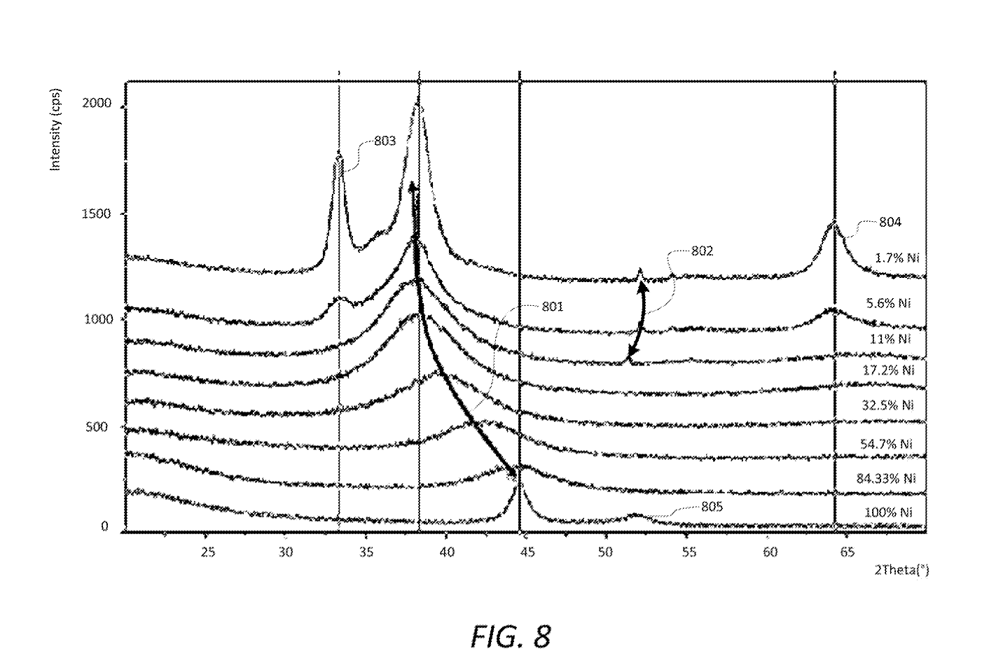

FIG. 8 is an example graph of X-ray diffraction (XRD) results plotting intensity (vertical axis) vs. 2-theta angle (horizontal axis) for mixed-metal barriers with different proportions of nickel as the ferromagnetic metal. Tantalum was the refractory metal and, in this particular experiment to isolate variables, the only other component. The test films had nickel ranging from a small amount (1.7%) to 100%. If the metals were combining as a simple mixture, one would expect pronounced tantalum peaks and very small nickel peaks in the top curve, pronounced nickel peaks and no tantalum peaks in the bottom curve, and superpositions of the two sets of peaks with varying relative size in between; that is, from the top curve to the bottom curve, the tantalum peaks would shrink and the nickel peaks would grow. While some of them (803, 804, and 805) appear to do that, two other peaks follow migration tracks 801 and 802. This non-superposing behavior suggests that some of the intermingling of the metals is alloying or something else more complex than simple mixing.

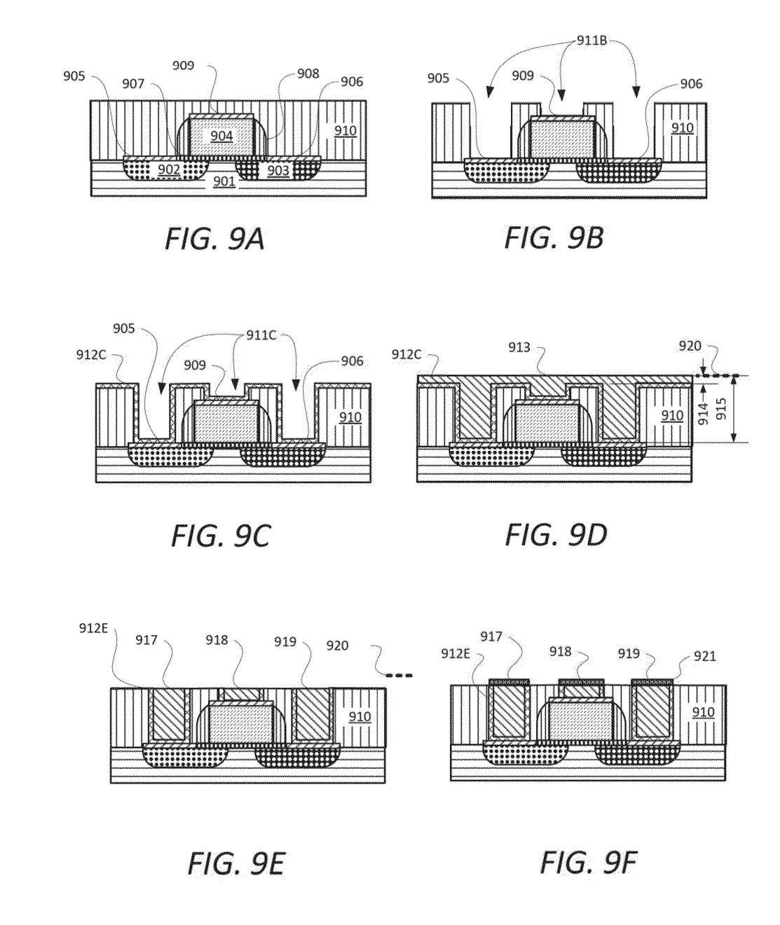

FIGS. 9A-9F conceptually illustrate a metallization process for device structure using a mixed-metal barrier that is substantially conductive. “Substantially conductive” means that on the scale of the device being built, enough current may pass through the mixed-metal barrier from one adjacent conductor to another to effectively create a short circuit.

FIG. 9A shows a structure temporarily buried under an insulator. In previous steps not shown here, an exemplary device structure (including a source 902, drain 903, gate 904, gate insulator 907, spacers 908, source electrode 905, drain electrode 906, gate electrode 909) has been constructed on substrate 901 (which may have layers below those shown here), and the structure was covered with an insulator 910. Insulator 910 may be an interlayer dielectric (ILD), may be a composite of more than one layer, and may include an oxide.

FIG. 9B shows the structure after creating one or more openings 911B through insulator 910 to expose one or more conductive contacts. In the illustrated example, the conductive contacts are surfaces of source electrode 905, gate electrode 906, and drain electrode 909, but the principle can be applied to any conductive contact buried under an insulator. The openings may be created by etching, lithography, micromachining, or any suitable method for creating openings in insulator 910 with the necessary precision. Openings 911B are shown with rectangular cross-sections for clarity, but other cross-sections such as inwardly-tapering, beveled, chamfered, or filleted may also be used. The exposed surfaces of the conductive contacts may be the original top surfaces of the contacts, as illustrated. In some embodiments not shown, some of the original top material may be removed, or a thin overcoating that allows the passage of electric current may be left on top of the original top surface of the contact.

FIG. 9C shows the structure with a mixed-metal barrier 912C conformally coating conductive contacts 905, 906, and 909 as well as the top surface of insulator 910 and the side walls of the openings 911B, leaving coated openings 911C. Coated openings 911C are shown with rectangular cross-sections for clarity, but other cross-sections such as inwardly-tapering, beveled, chamfered, or filleted may also be used. Some embodiments of mixed-metal barrier 912C may form a conformal coating of acceptable thickness, uniformity, and step-coverage as deposited (e.g., by sputtering). Some embodiments may begin by depositing an overly thick barrier 912C (i.e., thicker than the desired final thickness), then etching, micromachining, or otherwise modifying barrier 912C to achieve the desired thickness, uniformity, and step coverage on each of the various surfaces. Any suitable method known in the art for modifying an overly thick metallic layer to a desired thickness and contour may be used.

FIG. 9D shows the structure with a conducting material 913 deposited over mixed-metal barrier 912C to substantially fill coated openings 911C up to top level 920. The illustrated configuration, where barrier 912C remains between conducting material 913 and conductive contacts 905, 906, and 909, is suitable for embodiments of mixed-metal barrier 912C having conductivities and thicknesses that allow an operating current to pass from the conducting material through the mixed-metal barrier to a conductive contact (or in the opposite direction) without unacceptable loss or heat dissipation. In some embodiments, the thickness (e.g., 914 or 915) of the conducting material over at least one of coated openings 911C after deposition or other formation process is less than about 100 Å and the conducting material is contiguous at this thickness.

FIG. 9E shows the structure after an upper extent of conducting material 913 has been removed to form separate conductors 917, 918, 919, physically separated and electrically isolated by surrounding regions of insulator 910. Because the illustrated embodiment of mixed-metal barrier 912C is conductive, it is also removed from the top surface of insulator 910 to prevent unwanted short circuits between separate conductors 917, 918, and 919, so that only barrier liners 912E remain from the former conformal barrier 912C. Chemical-mechanical planarization (CMP), other types of planarization, etching, micromachining, or any other suitable known method may be used to remove the materials from former top level 920 to the desired level.

FIG. 9F illustrates an optional step of forming a second barrier 921 on top of the structure. The illustration shows second barrier 921 after a subsequent etch or other patterning step, so that it covers only conductors 917, 918, and 919. Second barrier 921 prevents diffusion from conductors 917, 918, or 919, whether the diffusion would otherwise be up over barrier liners 912E and into insulator 910 or straight up into other layers and structures to be formed above the structure of FIG. 9E. Second barrier 921 may be a mixed-metal barrier, and may have either the same composition as barrier liners 912E or a different composition.

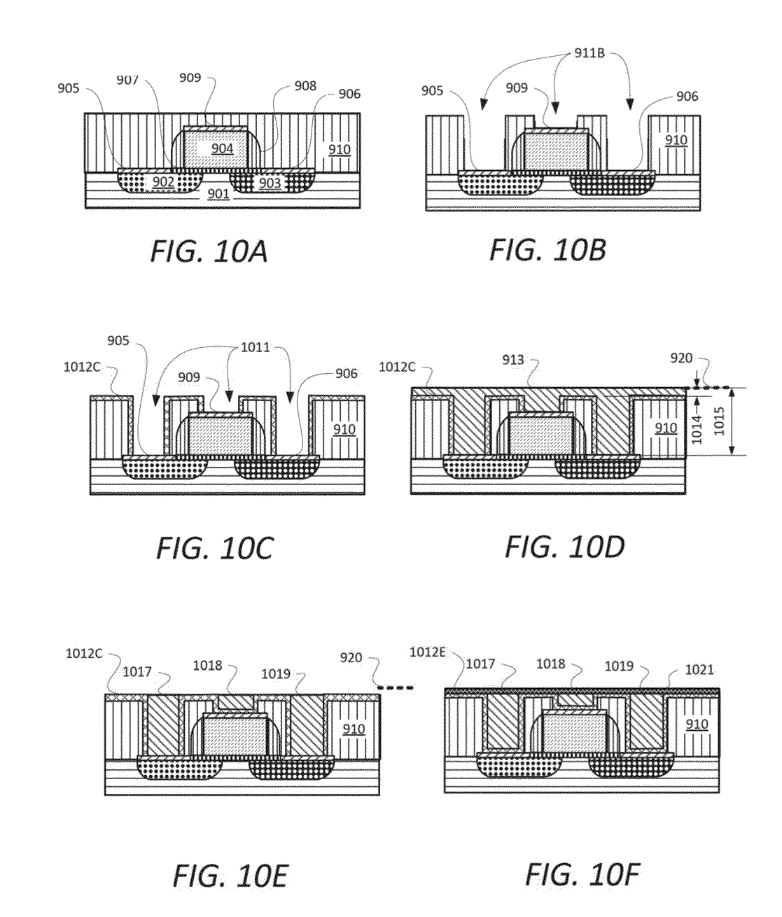

FIGS. 10A-10F conceptually illustrate a metallization process for a device structure using a mixed-metal barrier that is not substantially conductive. “Not substantially conductive” means that on the scale of the device being built, sufficient current to effectively create a short circuit cannot pass through the mixed-metal barrier from one adjacent conductor to another. For ease of understanding, the same underlying structure as in FIG. 9 is illustrated, although the methods and materials described herein are compatible with numerous other structures.

In FIG. 10A, an exemplary device structure (including a source 902, drain 903, gate 904, gate insulator 907, spacers 908, source electrode 905, drain electrode 906, gate electrode 909) has been constructed on substrate 901 (which may have layers below those shown here), and the structure was temporarily buried under an insulator 910. Insulator 910 may be an interlayer dielectric (ILD), may be a composite of more than one layer, and may include an oxide.

In FIG. 10B, openings 911B made through insulator 910 expose one conductive contacts (source electrode 905, gate electrode 906, and drain electrode 909); all the same variations discussed in relation to FIG. 9B are also applicable here.

In FIG. 10C, mixed-metal barrier 1012C is removed from portions of conductive contacts 905, 906, and 906 to create a path for current to flow, transforming openings 911B into partially-coated openings 1011.

In FIG. 10D, a conducting material 913 is deposited over mixed-metal barrier 1012C to substantially fill partially-coated openings 1011 up to top level 920. In some embodiments, the thickness of the conducting material (e.g., 1014 or 1015) over at least one of coated openings 1011 after deposition or other formation process is less than about 100 Å and the conducting material is contiguous at this thickness.

In FIG. 10E, an upper extent of conducting material 913 has been removed to form separate conductors 1017, 1018, 1019, physically separated and electrically isolated by surrounding regions of insulator 910 and by the substantially non-conductive embodiment of mixed-metal barrier 1012C. Because this embodiment of the mixed-metal barrier is substantially non-conductive and unlikely to cause a short circuit, some or all of it may remain on top of insulator 910, leaving its profile similar or identical to barrier 1012C. Chemical-mechanical planarization (CMP), other types of planarization, etching, micromachining, or any other suitable known method may be used to remove the materials from former top level 920 to the desired level.

In FIG. 10F, an optional second low-conductivity barrier 1021 is added over the structure of FIG. 10E. If the conductivity of second barrier 1021 is sufficiently low that it will not cause a short circuit between conductors 1017, 1018, and 1019, it may not need to be etched or otherwise patterned to cover only those conductors. Second barrier 1021 may be a mixed-metal barrier, and may have either the same composition as barrier 1012C or a different composition.

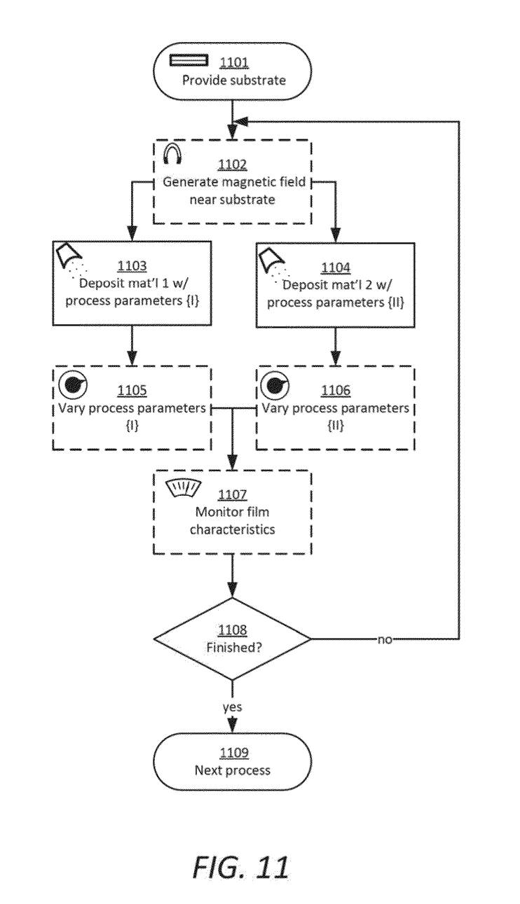

FIG. 11 is an example flowchart for forming a mixed-metal barrier by simultaneous deposition.

A substrate is provided 1101 and placed in the processing chamber. A magnetic field may optionally be generated 1102 near the substrate (for example, if one of the metals is ferromagnetic, it may be sputtered through the magnetic field). Simultaneously, material 1 is deposited 1103 subject to a first set {I} of process parameters, and material 2 is deposited 1104 subject to a second set {II} of process parameters. A set of process parameters may include plasma power or power density, throw distance from target to substrate, and angle between target and substrate. Some process parameters, such as substrate temperature or chamber pressure, may be elements of both sets.

During the deposition, one or more members of process parameter set {I} or process parameter set {II} may optionally be varied 1105 and/or 1106. Depending on which parameter is varied, a composition gradient or other physical or chemical gradient may be caused in the deposited layer. Optionally, the film characteristics are monitored 1107 for the occurrence of a desired condition, such as a specified thickness. Otherwise, the process may simply proceed for a set time that, given process parameter sets {I} and {II}, is known to produce the desired condition. The steps of this process continue until a “finished” condition occurs 1108: the target time elapses, the monitoring results indicate a finished layer, or the like). Then the next process (e.g., etching or deposition of another layer, such as a copper layer) can proceed 1109.

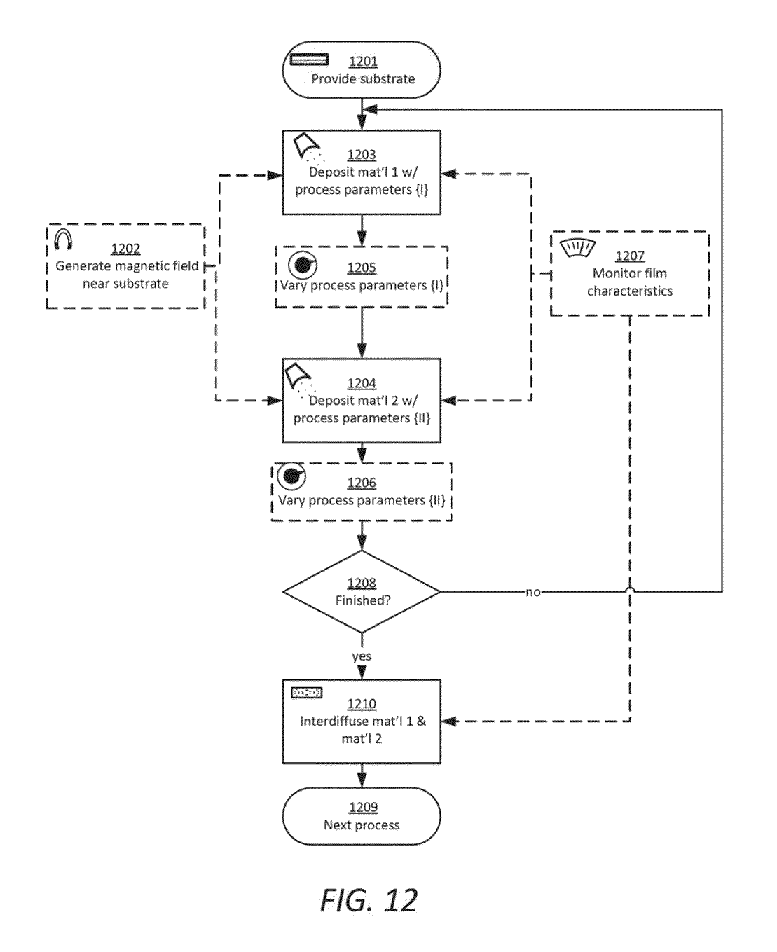

FIG. 12 is an example flowchart for forming a mixed-metal barrier by alternating-layer deposition.

A substrate is provided 1201 and placed in the processing chamber. Material 1 is deposited 1203 subject to a first set {I} of process parameters. Subsequently, material 2 is deposited 1204 subject to a second set {II} of process parameters. A magnetic field may optionally be generated 1202 near the substrate during deposition 1203 or deposition 1204 (for example, if one of the materials is ferromagnetic, it may be sputtered through the magnetic field). A set of process parameters may include plasma power or power density, throw distance from target to substrate, and angle between target and substrate. Some process parameters, such as substrate temperature or chamber pressure, may be elements of both sets.

During deposition 1203, one or more members of process parameter set {I} may optionally be varied 1205. During deposition 1204, one or more members of process parameter set {II} may optionally be varied 1206. Depending on which parameter is varied, a composition gradient or other physical or chemical gradient may be caused in the deposited layer. Optionally, the film characteristics are monitored 1207 for the occurrence of a desired condition, such as a specified thickness. Otherwise, the process may simply proceed for a set time that, given process parameter sets {I} or {II}, is known to produce the desired condition. Deposition 1203 and deposition 1204 continue, and/or may be alternatingly repeated, until a “finished” condition occurs 1208; the target time elapses, the monitoring results indicate a finished layer, or the like). Then the next process (e.g., etching or deposition of another layer, such as a copper layer) can proceed 1209.

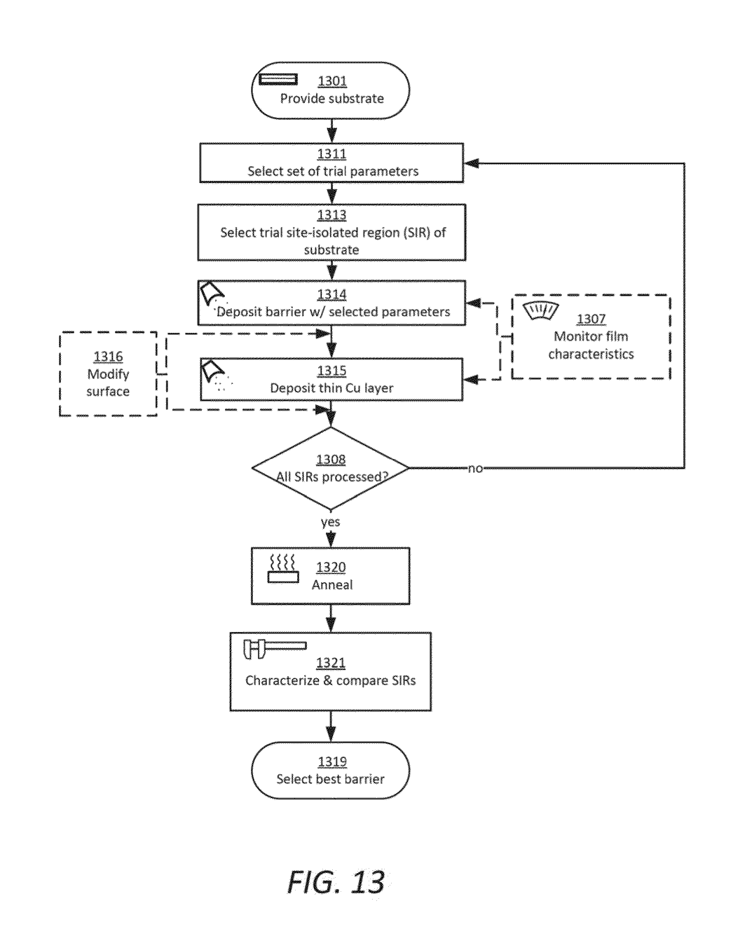

FIG. 13 is an example flowchart for HPC screening of candidate mixed-metal barriers.

A substrate is provided 1301 in a process chamber. The substrate has multiple site-isolated regions (SIRs) defined thereon, and may have existing layers, textures, or patterns such as trenches and plateaus. For each SIR, a set of trial process parameters is selected 1311. Parameters which can be varied include, but are not limited to, target composition, target plasma power density, target distance from the substrate, target angle relative to the substrate, sputter gases, ALD feedstock and ambient gases, purge gases and cycles, process temperature, process time, process pressure, order in which materials are deposited, simultaneity of sputtering from multiple targets, barrier thickness, barrier composition, gradients in the barrier, and variation of any of these while forming the barrier. In turn, each SIR is selected 1313; exposed for processing while the other areas of the substrate are shielded from processing. A barrier is deposited 1314 on the selected SIR using the selected parameters. Optionally, the barrier surface may be modified 1316; e.g., by etching or polishing. A thin (e.g., <100 Å) copper layer is deposited 1315 on the barrier layer. The surface of the copper layer may optionally be modified 1316.

While one or more SIRs remain to be processed, each SIR in turn is selected and processed using a set of selected parameters. At least one of the selected parameters may differ for each SIR, or some of the SIRs may be processed with identical parameters to act as controls or references. One or more SIRs may be intentionally left unprocessed as a reference. When all the SIRs intended for processing have been processed 1308, the substrate is annealed 1320. The SIRs are then characterized and compared 1321; e.g., the copper layer is checked for agglomeration. The barrier(s) with the best results are selected 1319 for the next stage of screening.

Although the foregoing examples have been described in some detail to aid understanding, the scope of invention is not limited to the details in the description and drawings. The examples are illustrative, not restrictive. There are many alternative ways of implementing the described concepts. Various aspects or components of the described embodiments may be used singly or in any combination. The scope is limited only by the claims, which encompass numerous alternatives, modifications, and equivalents.

What is claimed is:

1. A method of forming a mixed-metal barrier film, the method comprising:
depositing a first material and a second material on a substrate;
wherein the first material comprises a first refractory metal; and
wherein the second material comprises at least one of a ferromagnetic metal or a second refractory metal.

2. The method of claim 1, wherein the first material and the second material are deposited on the substrate simultaneously.

3. The method of claim 2, wherein the first material and the second material are co-sputtered from separate targets.

4. The method of claim 3, wherein the separate targets are sputtered at different plasma power densities, from different throw distances to the substrate, or from different angles relative to the substrate.

5. The method of claim 4, wherein a first target comprising the first material is sputtered at a plasma power density between about 6 W/cm² and about 10.2 W/cm². [0069]

6. The method of claim 4, wherein a second target comprising the second material is sputtered at a plasma power density between about 1.1 W/cm2 and about 4.5 W/cm².

7. The method of claim 4, wherein at least one of the plasma power and the throw distance is varied while the first material and the second material are deposited on the substrate.

8. The method of claim 3, wherein the second material is sputtered through a magnetic field exceeding about 100 gauss at the substrate.

9. The method of claim 1, wherein the first material and the second material are deposited as several alternating or interleaved sub-layers; and further comprising interdiffusing the first material and the second material.

10. The method of claim 9, wherein the first material and the second material are interdiffused by annealing.

11. The method of claim 1, wherein the first material comprises tantalum.

12. The method of claim 1, wherein the second material comprises at least one of nickel or titanium.

13. The method of claim 1, wherein a sputtering target for the second material is less than about 0.1-0.7 mm thick.

14. A thin-film stack, comprising:
a mixed-metal barrier comprising a first material and a second material; and
a contiguous conductor less than about 100 Angstroms thick near the mixed-metal barrier;
wherein the first material comprises a first refractory metal; and
wherein the second material comprises at least one of a ferromagnetic metal or a second refractory metal.

15. The thin-film stack of claim 14, wherein a ratio of the second material to the first material in the mixed-metal barrier is between about 0.2:1 and about 1:1.

16. The thin-film stack of claim 14, wherein between about 10% and about 50% of the composition of the mixed-metal barrier is the second material.

17. The thin-film stack of claim 14, wherein an X-ray diffraction spectrum of the mixed-metal barrier comprises features not present in a superposition of spectra of separate barrier-layer components.

18. The thin-film stack of claim 14, wherein the mixed-metal barrier blocks diffusion from the contiguous conductor at temperatures less than about 525 C.

19. The thin-film stack of claim 14, wherein the contiguous conductor comprises copper.

20. The thin-film stack of claim 14, wherein the mixed-metal barrier comprises a depth-wise composition gradient.
